(19) United States
(12) Patent Application Publication
(10) Pub. No.: US 2025/0349743 A1
(43) Pub. Date: Nov. 13, 2025

(54) SEMICONDUCTOR DEVICE WITH CRACK PREVENTION DAM STRUCTURE

(71) Applicant: SAMSUNG ELECTRONICS CO., LTD., Suwon-si (KR)

(72) Inventors: Junghyun ROH, Suwon-si (KR); Minryeong CHA, Suwon-si (KR)

(73) Assignee: SAMSUNG ELECTRONICS CO., LTD., Suwon-si (KR)

(21) Appl. No.: 19/092,260

(22) Filed: Mar. 27, 2025

(30) Foreign Application Priority Data
May 10, 2024 (KR) 10-2024-0062070

(51) Int. Cl. H01L 23/00; H01L 21/268; H01L 21/78

(52) U.S. Cl. CPC H01L 23/562; H01L 21/268; H01L 21/78

(57) ABSTRACT

A semiconductor device includes a substrate including a central region and an edge region surrounding the central region; and a passivation layer on the substrate, in which the passivation layer includes: a protection layer covering the central region of the substrate, a crack prevention dam extending in the edge region of the substrate to surround the protection layer, the crack prevention dam spaced apart from the protection layer, and a plurality of stress distribution connectors extending from an outer side surface of the protection layer to an inner side surface of the crack prevention dam, each stress distribution connector from the plurality of stress distribution connectors spaced apart from each other along the outer side surface of the protection layer to form a slit defined by at least four sides.

### CROSS-REFERENCE TO RELATED APPLICATIONS

This application claims priority under 35 U.S.C. § 119 to Korean Patent Application No. 10-2024-0062070, filed on May 10, 2024 in the Korean Intellectual Property Office (KIPO), the contents of which are herein incorporated by reference in their entirety.

### BACKGROUND

### 1. Field

Example embodiments relate to a semiconductor device. More particularly, example embodiments relate to a semiconductor device including a dam structure configured to prevent crack.

### 2. Description of the Related Art

External forces occurring during a manufacturing process of a semiconductor package may cause cracks in a semiconductor device. A crack-prevention dam structure may be provided in a scribe lane region that surrounds a die region. However, there is a risk that the dam structure may be lifted during the manufacturing process, thereby reducing a reliability of a product. Furthermore, it is necessary to effectively distribute external forces to prevent the occurrence of cracks.

### SUMMARY

Example embodiments provide a semiconductor device configured to prevent cracks and a lifting phenomenon of a dam structure.

According to one or more embodiments, a semiconductor device includes: a substrate including a central region and an edge region surrounding the central region; and a passivation layer on the substrate, in which the passivation layer includes: a protection layer covering the central region of the substrate, a crack prevention dam extending in the edge region of the substrate to surround the protection layer, the crack prevention dam spaced apart from the protection layer, and a plurality of stress distribution connectors extending from an outer side surface of the protection layer to an inner side surface of the crack prevention dam, each stress distribution connector from the plurality of stress distribution connectors spaced apart from each other along the outer side surface of the protection layer to form a slit defined by at least four sides.

According to one or more embodiments, a semiconductor device, including: a substrate including a central region and an edge region surrounding the central region; a front insulation layer on the substrate; a plurality of chip pads in the front insulation layer, the plurality of chip pads arranged along a side portion of the central region; and a passivation layer on the front insulation layer, in which the passivation layer includes: a protection layer covering the central region of the substrate, a crack prevention dam extending in the edge region of the substrate to surround the protection layer, the crack prevention dam spaced apart from the protection layer, and a plurality of stress distribution connectors extending from an outer side surface of the protection layer to an inner side surface of the crack prevention dam, each stress distribution connector form the plurality of stress distribution connectors spaced apart from each other along the outer side surface of the protection layer to form a slit defined by at least four sides.

According to one or more embodiments, a semiconductor device includes: a substrate including a central region and an edge region surrounding the central region; a front insulation layer on a front surface of the substrate; a plurality of chip pads in the front insulation layer, the plurality of chip pads arranged along a side portion of the central region; a passivation layer on the front insulation layer; and an adhesive film on a backside surface of the substrate, in which the passivation layer includes: a protection layer covering the central region of the substrate, a crack prevention dam extending in the edge region of the substrate to surround the protection layer, the crack prevention dam spaced apart from the protection layer, and a plurality of stress distribution connectors extending from an outer side surface of the protection layer to an inner side surface of the crack prevention dam, each stress distribution connector from the plurality of stress distribution connectors spaced apart from each other along the outer side surface of the protection layer, in which each of the plurality of stress distribution connectors comprise (i) a first portion connected to the crack prevention dam and (ii) a second portion connected to the protection layer and having a second width, in which the first portion has a first width and the second portion has a second width, and in which the first width is equal to the second width.

Accordingly, since the plurality of stress distribution connectors connect the crack prevention dam to the protection layer, the crack prevention dam may be prevented from lifting away from the semiconductor device. Furthermore, the plurality of stress distribution connectors may effectively distribute external forces transmitted from the crack prevention dam.

### BRIEF DESCRIPTION OF THE DRAWINGS

FIG. 1 is a plan view illustrating a semiconductor device in accordance with example embodiments.

FIG. 2 a cross-sectional view taken along the line C1-C1′ in FIG. 1 in accordance with example embodiments.

FIG. 3 is an enlarged view illustrating the ‘M1’ portion in FIG. 1 in accordance with example embodiments.

FIG. 4 is a perspective view illustrating the first passivation layer in FIG. 1 in accordance with example embodiments.

FIG. 5 a cross-sectional view taken along the line C2-C2′ in FIG. 3 in accordance with example embodiments.

FIGS. 6 to 20 are views illustrating a method of manufacturing a semiconductor device in accordance with example embodiments.

FIG. 21 is a plan view illustrating a passivation layer in accordance with example embodiments.

FIG. 22 is a perspective view illustrating the second passivation layer in FIG. 21 in accordance with example embodiments.

FIG. 23 a cross-sectional view taken along the line C5-C5′ in FIG. 21 in accordance with example embodiments.

FIGS. 24 to 29 are views illustrating a method of manufacturing a semiconductor device in accordance with example embodiments.

FIG. 30 is a plan view illustrating a passivation layer in accordance with example embodiments.

FIG. 31 a cross-sectional view taken along the line C6-C6′ in FIG. 30 in accordance with example embodiments.

FIG. 32 is a plan view illustrating a passivation layer in accordance with example embodiments.

FIG. 33 is a plan view illustrating a passivation layer in accordance with example embodiments.

### DETAILED DESCRIPTION OF EXAMPLE EMBODIMENTS

Hereinafter, example embodiments will be explained in detail with reference to the accompanying drawings.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

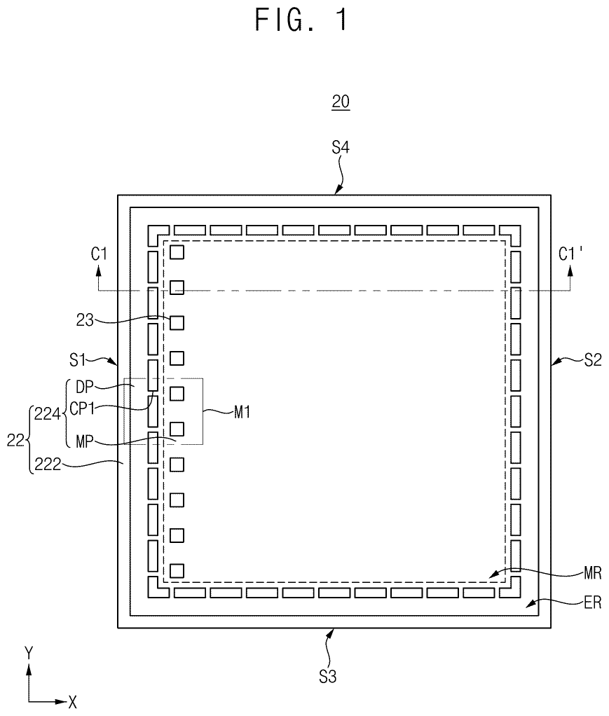

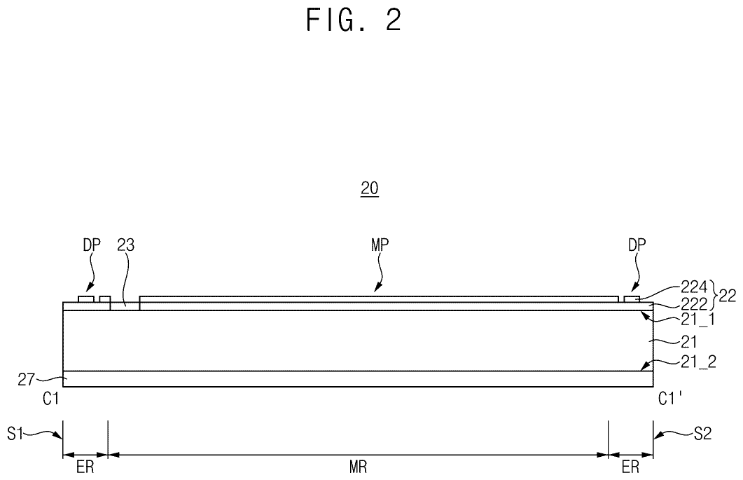

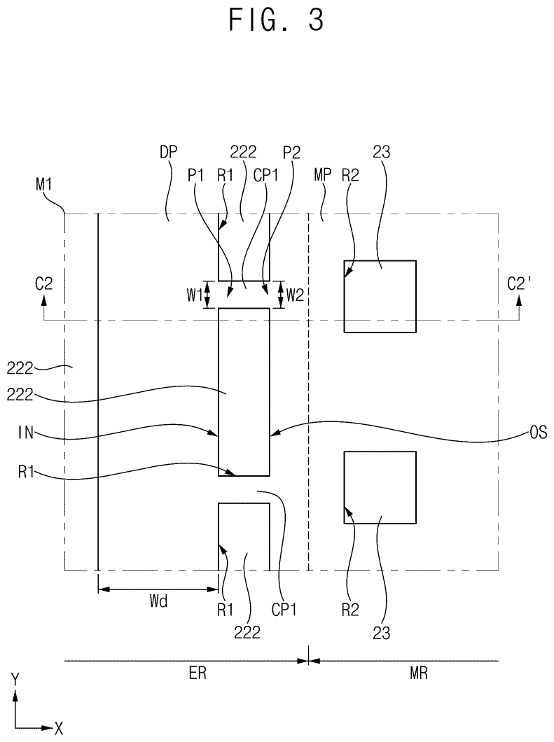

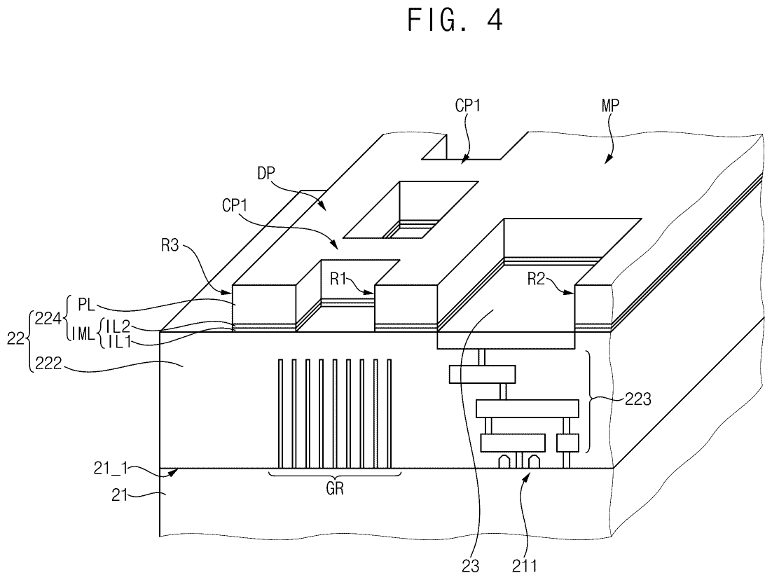

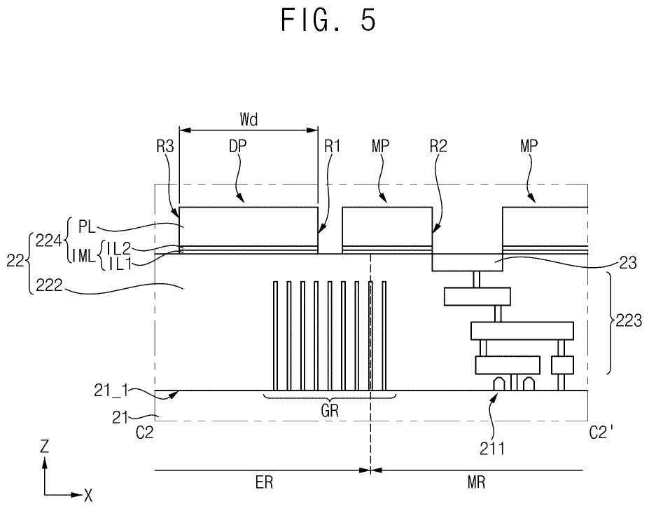

FIG. 1 is a plan view illustrating a semiconductor device in accordance with example embodiments. FIG. 2 a cross-sectional view taken along the line C1-C1′ in FIG. 1. FIG. 3 is an enlarged view illustrating the ‘M1’ portion in FIG. 1. FIG. 4 is a perspective view illustrating the first passivation layer in FIG. 1. FIG. 5 a cross-sectional view taken along the line C2-C2′ in FIG. 3.

Referring to FIGS. 1 to 5, a semiconductor device 20 may include a substrate 21, an insulation layer 22 provided on a front surface 21_1 of the substrate 21, a plurality of chip pads 23 provided within the insulation layer 22, and an adhesive film 27 provided on a backside surface 21_2 of the substrate 21, respectively. For example, the front surface may be an active surface on which electronic elements such as transistors are formed. In contrast, the backside surface may be an inactive surface. For example, the adhesive film may be a die attach film (DAF).

For example, the semiconductor device may include a volatile memory device, such as a DRAM, or a non-volatile memory device, such as a NAND flash memory, or any other suitable memory structure known to one of ordinary skill in the art. In one or more examples, the semiconductor device may include a processor chip such as an ASIC, an application processor (AP) as a host such as a CPU, GPU, SOC, or any other processor structure known to one of ordinary skill in the art.

In example embodiments, the substrate 21 may include a front surface 21_1, which provides a central region MR disposed at a center and an edge region ER surrounding the central region MR, and a backside surface 21_2 facing the front surface 21_1. For example, the central region MR may be a region in which electronic elements, to be described later, are provided. Further, the central region MR may have a rectangular shape when viewed in a plan view. However, as understood by one of ordinary skill in the art, the embodiments are not limited to this configuration, and the central region MR may have any suitable shape such as a square shape.

The substrate 21 may include a first side portion S1 and a second side portion S2 extending in a first direction (Y direction) and facing each other. Further, the substrate 21 may include a third side portion S3 and a fourth side portion S4 extending in a second direction (X direction) perpendicular to the first direction (Y direction) and facing each other. For example, the substrate may have a square shape when viewed in a plan view.

For example, the substrate 21 may include a plurality of electronic elements 211 provided on the central region MR of the front surface 21_1. However, it will be understood that the present embodiments are not limited thereto, where the plurality of electronic elements 211 can be varied. In one or more examples, a passivation layer may be a thin layer that protects the active surface of a semiconductor from the surrounding environment. Passivation layers may be applied using evaporation, sputtering, or chemical vapor deposition. Passivation layers may reduce charge recombination at surface states, protect a semiconductor from chemical corrosion, protect an active surface from particles, and lower leakage current on devices.

In example embodiments, the insulation layer 22 may include a front insulation layer 222 and a first passivation layer 224 sequentially stacked on the front 21_1 of the substrate 21. The insulating layer 22 may further include a plurality of wirings 223 disposed on the central region MR of the front surface 21_1. For example, the plurality of wirings may include a conductive metallic material. However, it will be understood that the present embodiments are not limited thereto, where the plurality of wires 223 can be varied.

The insulation layer 22 may include a plurality of guide rings GR (FIG. 4) provided in a region adjacent to the first to fourth side portions S1, S2, S3 and S4 of the substrate 21 and extending from the central region MR to the edge region ER. For example, the plurality of guide rings may be structures configured to reduce stress transmitted to the central region from an outside. For example, the plurality of guide rings may have a rectangular shape surrounding the central region, when viewed in a plan view. The plurality of guide rings may include a metallic material, such as copper (Cu) or the like. However, it will be understood that the embodiments are not limited thereto, where the number and shape of the plurality of guide rings GR can be varied. In one or more examples, a first guide ring GR from the plurality of guide rings and a second guide ring GR from the plurality of guide rings may have different shapes.

The first passivation layer 224 may include a plurality of interlayer insulation films (IML) and a photosensitive layer (PL) sequentially stacked on the front insulation layer 222 (FIG. 4). Further, the plurality of interlayer insulation films (IML) may include a first insulation film (IL1) and a second insulation film (IL2) stacked sequentially. For example, the first insulation film may include a material such as silicon dioxide (SiO₂). The second insulation film may include a material such as silicon nitride (SiN), etc. The photosensitive layer may include a photosensitive material, such as a photosensitive polyimide (PSPI), etc. The photosensitive material may be a positive type, in which bonds in an illuminated portion are weakened when the illuminated portion receives light, or a negative type, in which bonds in an illuminated portion are strengthened when the illuminated portion receives light.

In example embodiments, the plurality of chip pads 23 may be disposed within the central region MR adjacent to the plurality of side portions S1, S2, S3, and S4 and provided within the front insulation layer 222 such that at least a portion of each of the plurality of chip pads is exposed. For example, the plurality of chip pads 23 may be arranged along the first side portion S1 and disposed within the central region MR. Further, each of the plurality of chip pads 23 may be electrically connected with the plurality of wirings 223. For example, each of the plurality of chip pads may include a conductive metallic material.

While only a few chip pads are illustrated in the figures, it will be understood that the number, shape, and arrangement of the chip pads are provided are merely exemplary.

The first passivation layer 224 may include a protection layer MP covering the central region MR in which at least one uncovered portion of the central region MR exposes the plurality of chip pads 23, a crack prevention dam DP extending in the edge region to surround the protection layer MP and spaced apart from the protection layer MP, and a plurality of first stress distribution connectors CP1 connecting the protection layer MP and the crack prevention dam DP, respectively. The crack prevention dam may be a structure configured to prevent an external force, which is applied externally to the semiconductor device, from being transmitted to the central region MR, which includes the electronic elements. Further, the plurality of first stress distribution connectors may be structures configured to prevent the crack prevention dam from separating from the front insulation layer 222 and configured to effectively distribute the external force.

The first passivation layer 224 may include a plurality of first slits R1 disposed between the protection layer MP and the crack prevention dam DP, respectively, and provided on both side portions of each of the plurality of first stress distribution connectors CP1, a plurality of second slits R2 disposed in the central region MR to expose each of the plurality of chip pads 23, and a third slit R3 surrounding the crack prevention dam DP along a plurality of side portions S1, S2, S3 and S4 (FIG. 1). The front insulation layer 222 may be exposed from each of the plurality of first slits R1 and third slits R3.

For example, the plurality of first stress distribution connectors may extend from an outer surface OS of the protection layer MP to an inner surface IN of the crack prevention dam DP, and the plurality of first stress distribution connectors may be spaced apart from each other along the outer surface OS of the protection layer MP to form a first slit of a quadrilateral shape (e.g., slit is defined by four sides).

The protection layer MP may be provided on the central region MR and a portion of the edge region ER. Thus, the first passivation layer 224 may sufficiently cover the central region MR.

The plurality of first stress distribution connectors CP1 may include a first portion P1 connected to the crack prevention dam DP and a second portion P2 connected to the protection layer MP. The first portion P1 may have a first width W1 and the second portion P2 may have a second width W2. For example, the first width may be equal to the second width. Thus, each of the plurality of first stress distribution connectors may have a rectangular shape, when viewed in a plan view. However, as understood by one of ordinary skill in the art, the stress distribution connectors are not limited to this configuration and may be formed in any suitable shape (e.g., square, etc.).

The crack prevention dam DP may have a third width Wd. The third width Wd may be changed depending on an external force, which acts on the semiconductor device. As the third width Wd increases, the external force, which is transmitted to the central region MR, may decrease. For example, the third width may be within a range of 3 μm to 25 μm.

As described above, the semiconductor device may include the substrate 21, the front insulation layer 222 covering the front surface 21_1 of the substrate 21, the plurality of chip pads 23 provided within the front insulation layer 222, and the first passivation layer 224 provided on the front insulation layer 222. The first passivation layer may include the protection layer MP covering the central region MR of the substrate 21, the crack prevention dam DP extending in the edge region ER of the substrate 21 to surround the protection layer MP and spaced apart from the protection layer MP, and the first plurality of stress distribution connectors CP1 extending from the outer surface OS of the protection layer MP to the inner surface IN of the crack prevention dam DP and spaced apart from each other along the outer surface OS of the protection layer MP to form the slit R1 of quadrilateral.

Accordingly, the first plurality of stress distribution connectors may connect the crack prevention dam to the protection layer, thereby preventing lifting of the crack prevention dam away from the semiconductor device. Further, the plurality of first stress distribution connectors may effectively distribute the external force, which is transmitted from the crack prevention dam.

Hereinafter, a method for manufacturing the semiconductor device 20 in FIG. 1 will be described.

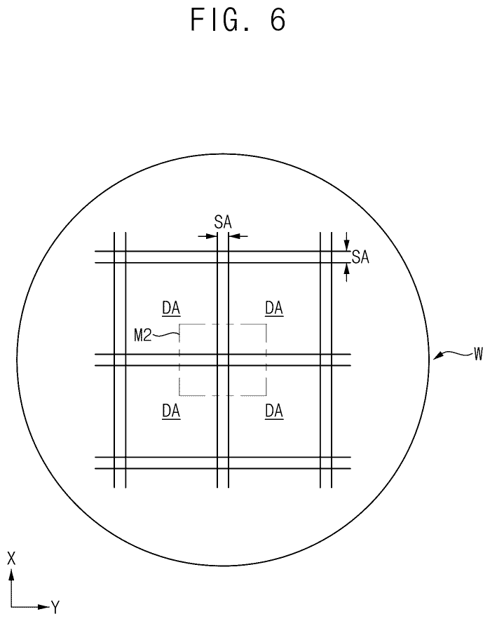

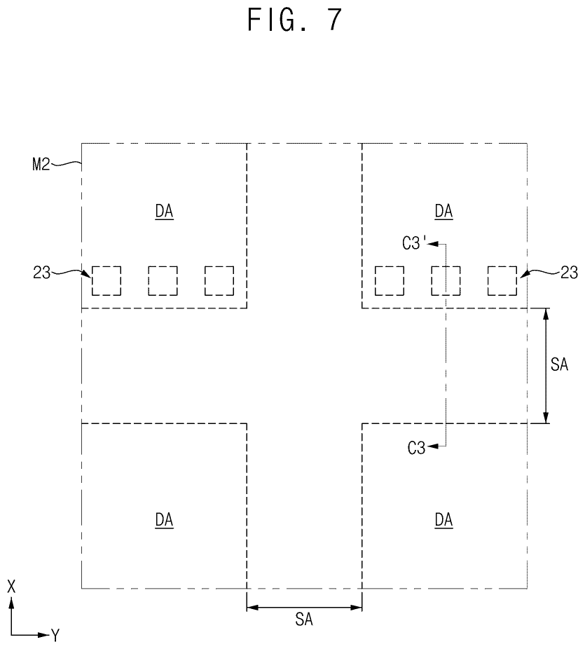

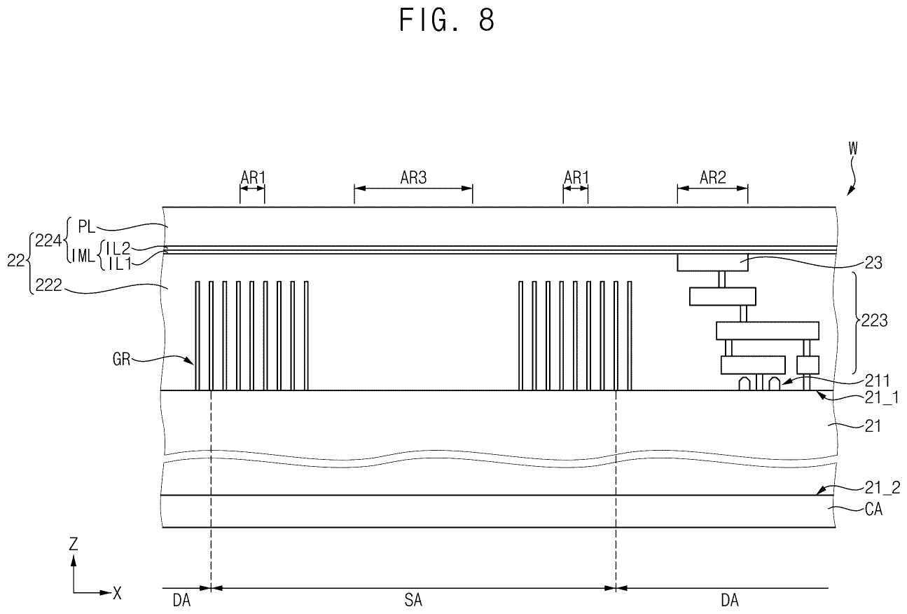

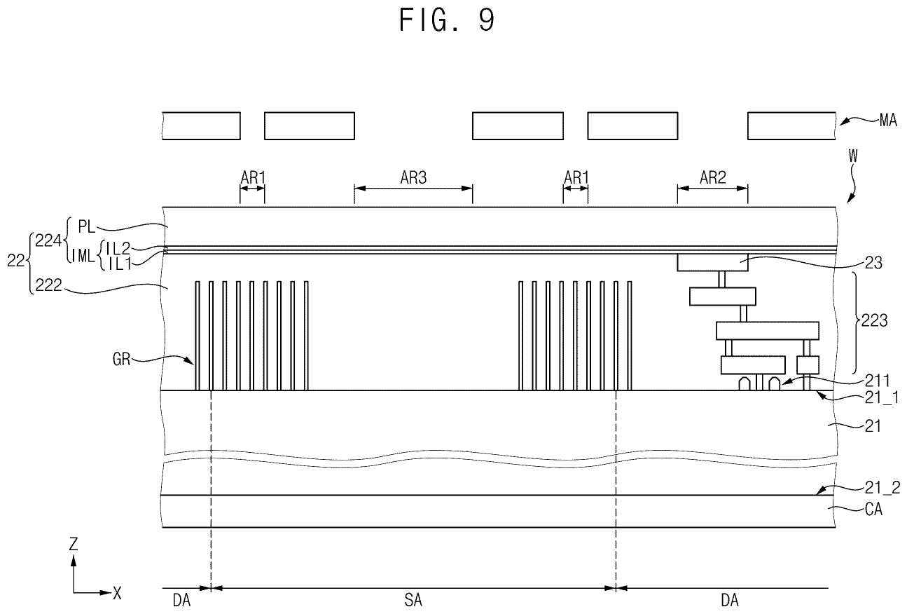

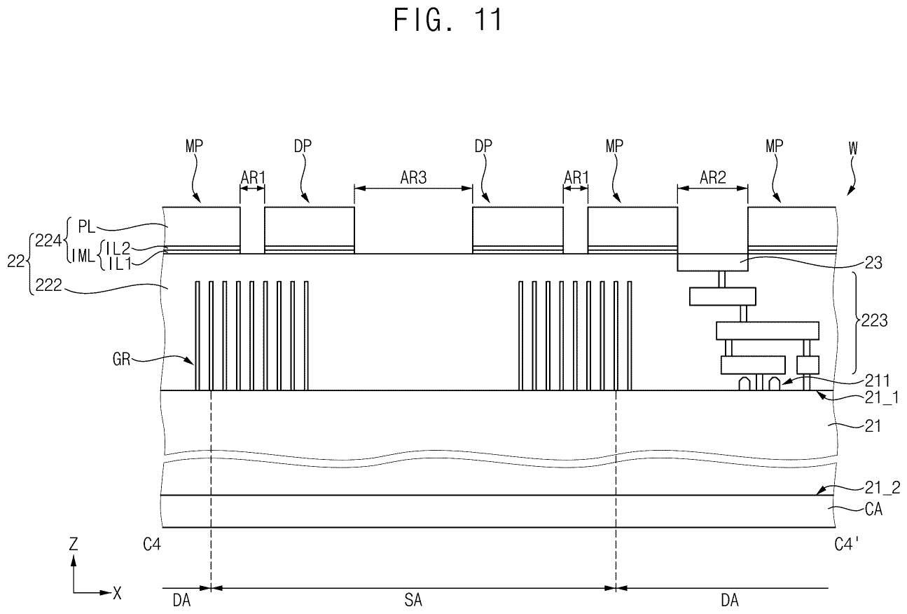

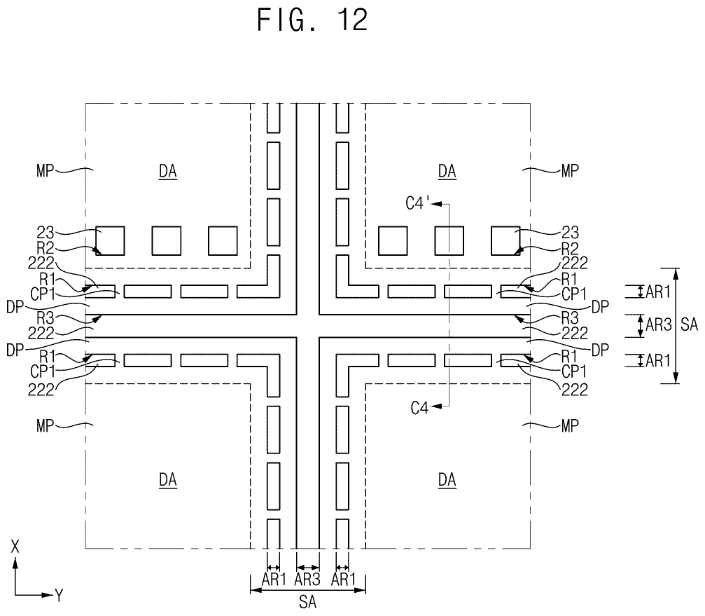

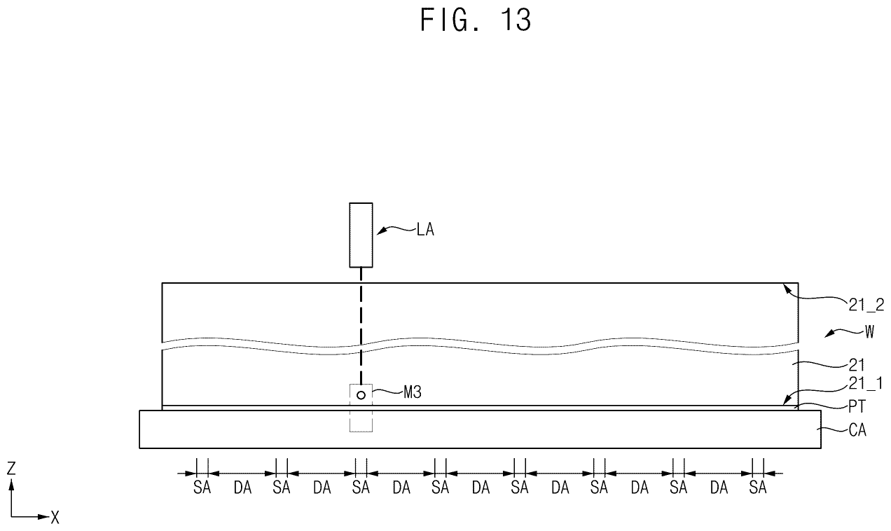

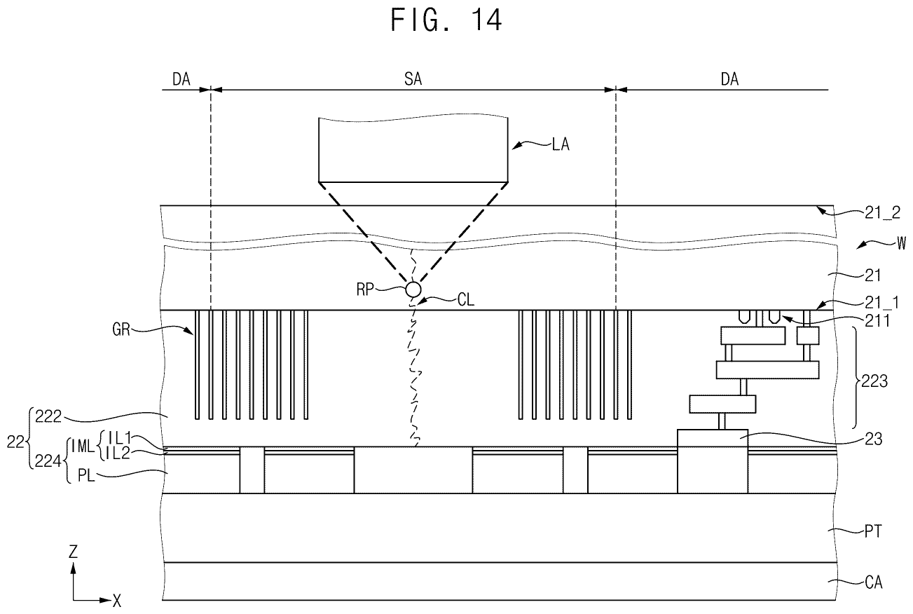

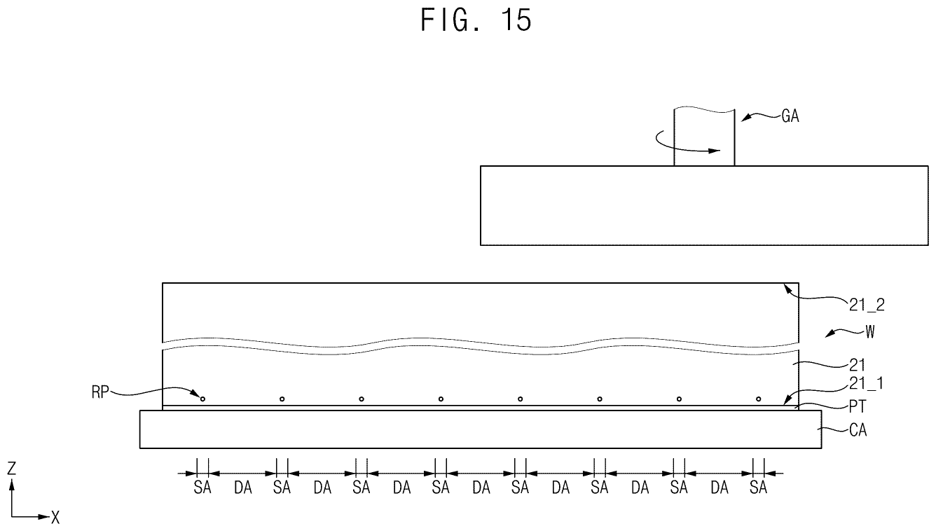

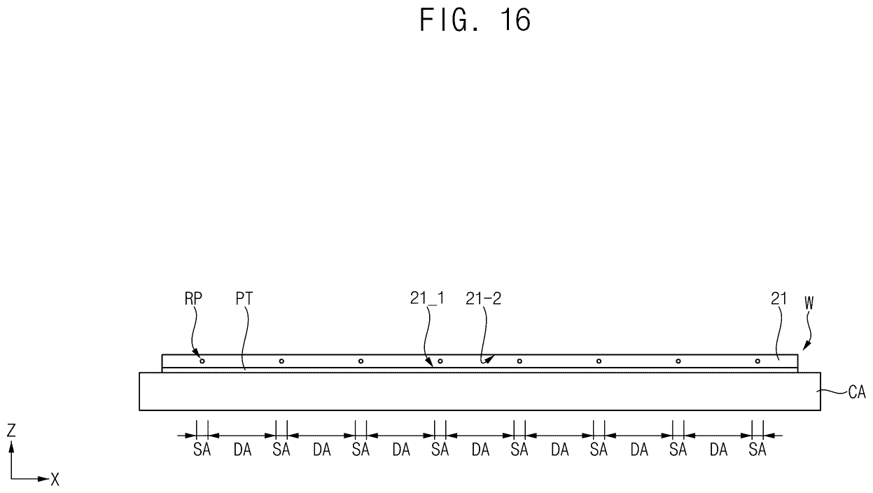

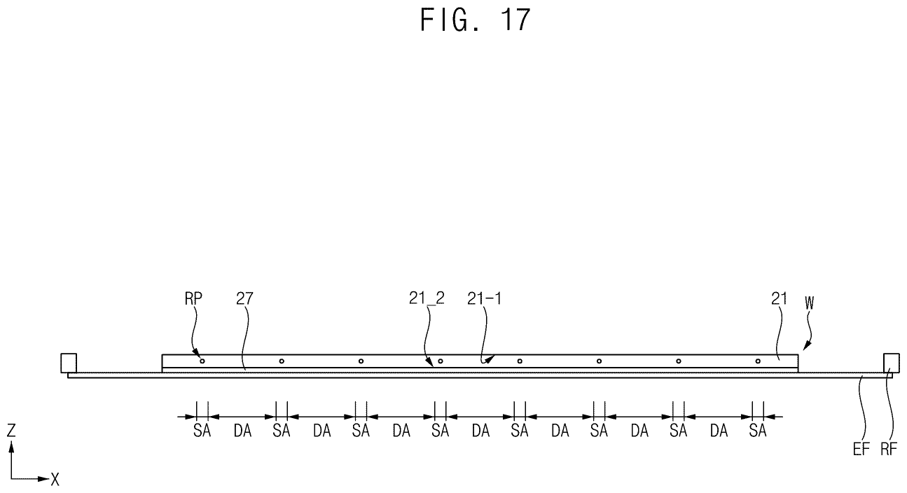

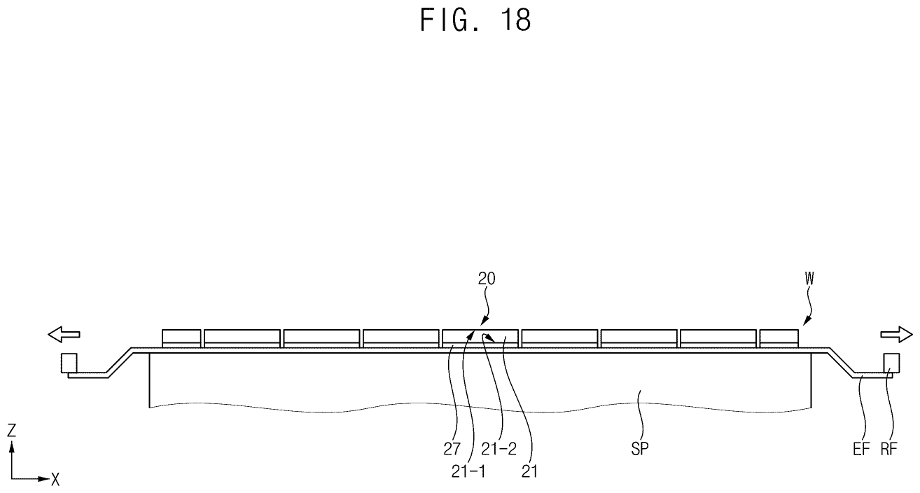

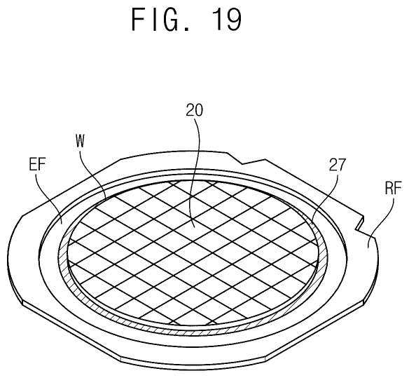

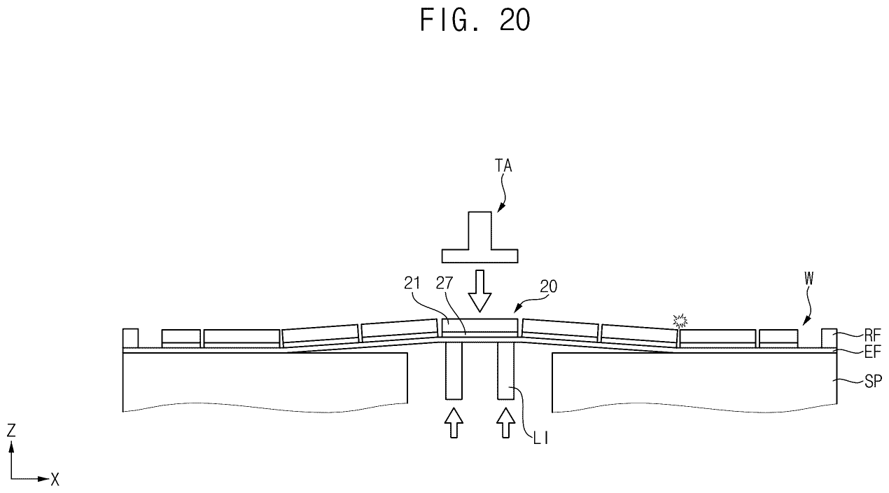

FIGS. 6 to 8 are views illustrating providing a wafer having a passivation layer in accordance with an example embodiment. FIG. 7 is an enlarged view illustrating ‘M2’ portion in FIG. 6. FIG. 8 is a cross-sectional view taken along the line C3-C3′ in FIG. 7. FIGS. 9 to 12 are views illustrating partially removing the passivation layer. FIG. 11 is a cross-sectional view taken along the C4-C4′ line in FIG. 12. FIGS. 13 and 14 are views illustrating forming cracks in the scribe lane region. FIG. 14 is an enlarged cross-sectional view illustrating ‘M3’ portion in FIG. 13. FIGS. 15 and 16 are views illustrating partially removing the wafer by performing a grinding process. FIG. 17 is a view illustrating securing the wafer via an adhesive film on a ring frame. FIG. 18 is a view illustrating, after cooling the adhesive film, expanding the wafer to individualize the wafer into semiconductor devices. FIG. 19 is a perspective view illustrating a ring frame on which the individualized semiconductor devices are secured. FIG. 20 is a view illustrating picking up the semiconductor devices one by one.

Since the semiconductor device manufactured by the manufacturing method illustrated in FIGS. 6 to 20 is substantially identical to the semiconductor device 20 described in FIGS. 1 to 5, identical components are denoted by the same reference numerals, and repeated descriptions of identical components are omitted.

Referring FIGS. 6 to 8, a wafer W, which includes a plurality of die regions DA and a scribe lane region SA surrounding the plurality of die regions DA, may be provided on a carrier CA. For example, the plurality of die regions may be regions including electronic elements. The scribe lane region may be region for separating and individualizing semiconductor devices by a process to be described later.

The wafer W may include a substrate 21 having a front surface 21_1 and a backside surface 21_2 facing each other, an insulation layer 22 covering the front surface 21_1 of the substrate 21, and a plurality of chip pads 23 arranged along a side portion of each of the plurality of die regions DA and provided within the insulation layer 22.

The substrate 21 may include a plurality of electronic elements 211 provided on the front surface 21_1 and disposed in the plurality of die regions DA.

The insulation layer 22 may include a front insulation layer 222 and a first passivation layer 224 sequentially stacked on the front surface 21_1 of the substrate 21. The insulation layer 22 may further include a plurality of wirings 223 disposed on the front surface 21_1 of the substrate 21 and disposed within the plurality of die regions DA. Each of the plurality of chip pads 23 may be electrically connected to the plurality of wirings 223. For example, the first passivation layer may be formed by a spin coating process.

The insulation layer 22 may include a plurality of guide rings GR provided on the front surface 21_1 of the substrate 21 and extending from each of the plurality of die regions DA to the scribe lane region SA. For example, the guide rings may be structures configured to reduce stresses transmitted to the central region from the outside. When viewed in a plan view, the guide rings may have a rectangular shape surrounding the die region. However, as understood by one of ordinary skill in the art, the number and shape of the guide rings are not limited to these configurations. For examples, the guide rings may include a first guide ring and a second guide ring having different shapes. The guide ring may include a metallic material, such as copper (Cu), etc.

The first passivation layer 224 may include a plurality of interlayer insulation films IML and a photosensitive layer PL stacked sequentially on the front insulation layer 222. Further, the plurality of interlayer insulation films IML may include a first insulation film IL1 and a second insulation film IL2 stacked sequentially.

The first passivation layer 224 may include a first region AR1 adjacent to the plurality of die regions DA and surrounding each of the plurality of die regions DA, a second region AR2 provided on the plurality of chip pads 23, and a third region AR3 disposed in a center portion of the scribe lane region SA.

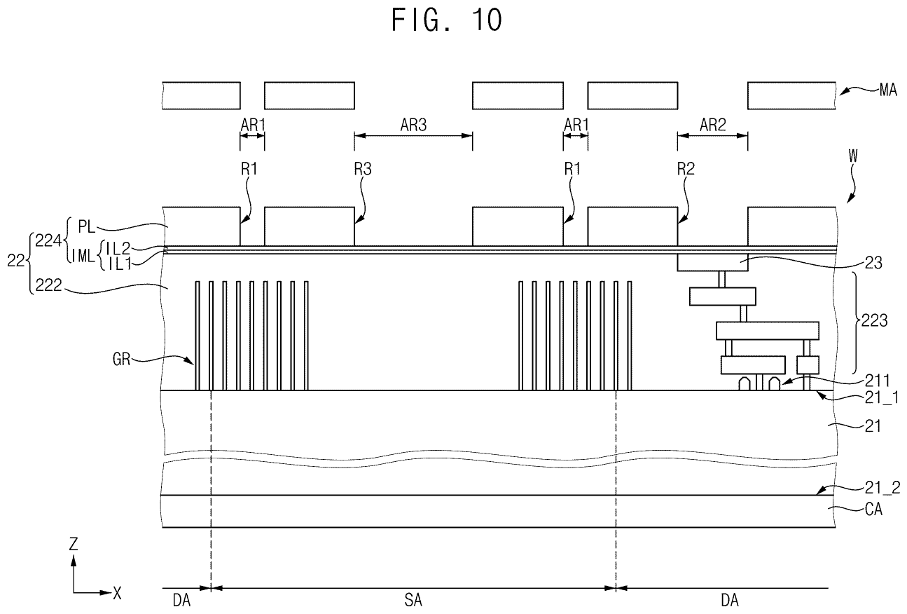

Referring to FIGS. 9 and 10, an exposure process may be performed on the first passivation layer 224 to selectively irradiate the first region AR1, the second region AR2, and the third region AR3 with light. Then, a develop process may be performed on the first passivation layer 224 to form a plurality of first slits R1 on the first region AR1, and to form a plurality of second slits R2 on the second region AR2, and to form a plurality of third slits R3 on the third region AR3, respectively.

For example, a mask MA having a pattern corresponding to the first region AR1, the second region AR2, and the third region AR3 may be positioned on upper portion of the first passivation layer 224, and light may be irradiated onto the first passivation layer 224 through the mask MA to selectively irradiate only the first region AR1, the second region AR2, and the third region AR3. Thus, the light-irradiated portion of the first passivation layer 224 may weaken bonds between materials.

Subsequently, a developer may be provided onto the upper portion of the first passivation layer 224 to partially remove the photosensitive layer PL in the first regions AR1, the second regions AR2, and third region AR3. The plurality of first slits R1, the plurality of second slits R2, and the plurality of third slits R3 may expose the plurality of interlayer insulation films IML.

In FIGS. 9 and 10, the first passivation layer 224 may be illustrated as a positive type photosensitive material, in which the bonding of the illuminated portion is weakened, but it will be appreciated that the embodiments are not limited to this configuration. Accordingly, the first passivation layer 224 may be a negative type photosensitive material, in which the bonding of the illuminated portion is strengthened. In this case, the mask MA may have a pattern that selectively blocks light only to the first regions AR1, the second regions AR2, and the third region AR3.

Referring to FIGS. 11 and 12, an etching process may be performed on the plurality of interlayer insulation films IML, which is exposed by the plurality of first slits R1, the plurality of second slits R2, and the third slit R3, to form a pattern on the first passivation layer 224.

For example, the etching process may be a dry etching process in which a gas is injected onto the plurality of interlayer insulation films IML to partially remove the plurality of interlayer insulation films IML. The gas may include a material such as carbon tetrafluoride (CF4), etc.

The pattern may include a protection layer MP, a crack prevention dam DP, and a plurality of first stress distribution connectors CP1. The pattern may also include the plurality of first slits R1, the plurality of second slits R2, and the third slit R3.

The protection layer MP may cover a plurality of die regions DA to expose a plurality of chip pads 23. The protection layer MP may be provided over a portion of the plurality of die regions DA and the scribe lane region SA. Thus, the first passivation layer 224 may sufficiently cover the plurality of die regions DA.

The crack prevention dam DP may extend within the scribe lane region SA to surround the protection layer MP, and the crack prevention dam DP may be spaced apart from the protection layer MP. The crack prevention dam may be a structure configured to prevent external force from being transmitted to the plurality of die regions DA, which includes the electronic elements.

The plurality of first stress distribution connectors CP1 may connect the protection layer MP and the crack prevention dam DP, respectively. The plurality of first stress distribution connectors may be structures configured to prevent the crack prevention dam from separating from the front insulation layer 222, The plurality of first stress distribution connectors may be structures configured to effectively distribute the external force.

The plurality of first slits R1 may be located between the protection layer MP and the crack prevention dam DP, respectively, and the plurality of first slits R1 may be provided on both side portions of each of the plurality of first stress distribution connectors CP1. The plurality of second slits R2 may be respectively located within the plurality of die regions MR to expose a plurality of chip pads 23. The third slit R3 may be disposed along a side portion of each of the plurality of die regions DA to surround the crack prevention dam DP.

For example, the plurality of first stress distribution connectors may extend from the outer surface OS of the protection layer MP to the inner surface IN of the crack prevention dam DP, and the plurality of first stress distribution connectors may be spaced apart from each other along the outer surface OS of the protection layer MP to form the plurality of first slits.

The front insulation layer 222 may be exposed from the plurality of first slits R1 and the third slit R3, respectively.

Referring to FIGS. 13 and 14, a laser may be irradiated on the wafer W to form a modified portions RP in the scribe lane region SA and a guide line CL extending in a vertical direction (Z direction) from the modified portion RP. For example, the modified portion may be a portion that vaporizes a portion of a silicon wafer. The guide line may be a crack line that is intentionally formed to separate the wafer W along the scribe lane region SA.

In particular, a protective tape PT may be attached to the first passivation layer 224 to protect the front surface 21_1 of the wafer W. Subsequently, the wafer W may be provided on a carrier CA such that the front surface 21_1 of the wafer W faces the carrier CA.

A laser apparatus LA may be positioned on the backside surface 21_2 of the wafer W, and the laser device LA may be moved in a horizontal direction to irradiate the laser onto the scribe lane SA.

Referring to FIGS. 15 and 16, a grinding apparatus GA may be positioned on the backside surface 21_2 of the wafer W, and a grinding process may be performed to partially remove the wafer W. In one or more examples, the grinding process thins down semiconductor wafers to achieve the desired thickness, surface quality, and planarity. The grinding process is advantageous since thinner wafers can lead to smaller, lighter, and more power-efficient devices. In one or more examples, the grinding process may use an abrasive grinding wheel is used to carefully remove material from the backside of the wafer. The grinding process may include an operation of coarse grinding in which a large grit is used to remove excess thickness and an operation of polishing in which a finer grit is used to polish the wafer and grind the wafer to a desired thickness.

In this case, during the process of grinding the wafer W, collisions between adjacent die regions may occur. Further, an external force may be generated by the grinding apparatus. Due to the collisions and the external forces, cracks may occur in the wafer W.

Since the first passivation layer 224 of the wafer W includes the crack prevention dam DP and the plurality of first stress distribution connectors CP1, respectively, stresses and external forces generated by the collisions may be effectively distributed to prevent the cracks from occurring. In particular, cracks in the die regions DA may be prevented from occurring.

Furthermore, the plurality of first stress distribution connectors CP1 may prevent the lifting phenomenon, in which the crack prevention dam DP is separate or detached from the semiconductor device.

Referring to FIGS. 17 to 19, the wafer W may be secured to a ring frame RF. Subsequently, the ring frame RF may be expanded in the horizontal direction, and the plurality of die regions DA may be individualized along the scribe lane region SA to complete the semiconductor device 20.

The ring frame RF and the connecting film EF that is coupled to the ring frame RF may be positioned on lower portion of the wafer W, and the wafer W may be positioned on the connecting film EF such that the backside surface 21_2 of the wafer W faces the connecting film EF. Using the adhesive film 27 provided between the wafer W and the connecting film EF, the wafer W may be secured on the connecting film EF. The ring frame RF, the connecting film EF, and the wafer W may be a structure configured to effectively move and manage the wafer W during the manufacturing process.

The wafer W may then be positioned on a support member SP such that the connecting film EF is in contact with the support member SP. After cooling the adhesive film 27, the ring frame RF may be expanded in the horizontal direction to individualize the wafer W and the adhesive film 27 along the scribe lane region SA. At this time, the wafer W may be seperated along the guiding lines CL described above.

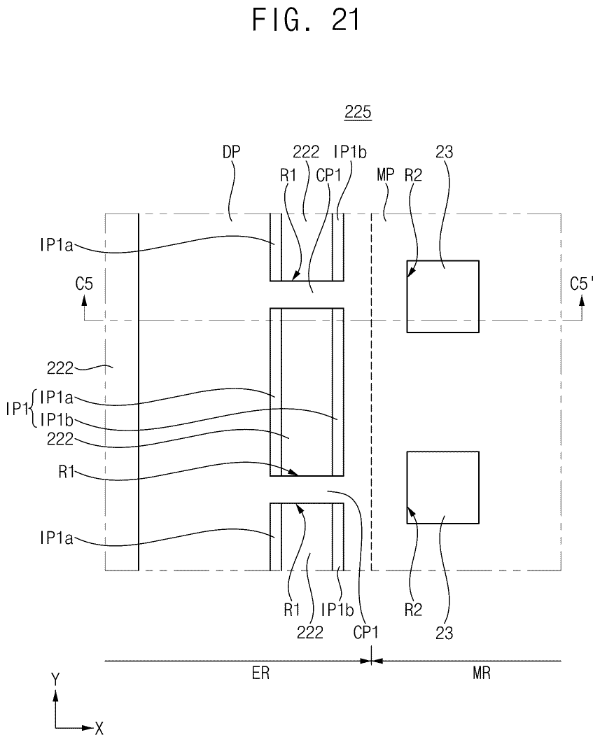

Referring to FIG. 21, the semiconductor device 20 may be picked up and moved using a die attach apparatus.

The semiconductor device 20 may be picked up and moved by using a pick-up apparatus TA and a lifting apparatus LI of the die attach apparatus, and the semiconductor device 20 may be attached to a package substrate.

At this time, during the process of picking up and moving the semiconductor device 20, collisions between adjacent semiconductor devices may occur. In addition, an external force may be generated by the die attach apparatus. Due to the collision and the external force, a crack may occur in the semiconductor device 20.

Since the first passivation layer 224 of the semiconductor device 20 includes a crack prevention dam DP and a plurality of first stress distribution connectors CP1, the stress generated by the collisions and the external forces may be effectively distributed to prevent the cracks from occurring. In particular, it is possible to advantageously prevent the cracks from occurring in the central region MR of the semiconductor device 20.

Furthermore, the plurality of first stress-distribution connectors CP1 may prevent a lifting phenomenon, in which the crack prevention dam DP is separate or detached from the semiconductor device.

Hereinafter, a second passivation layer 225 in accordance with example embodiments will be described.

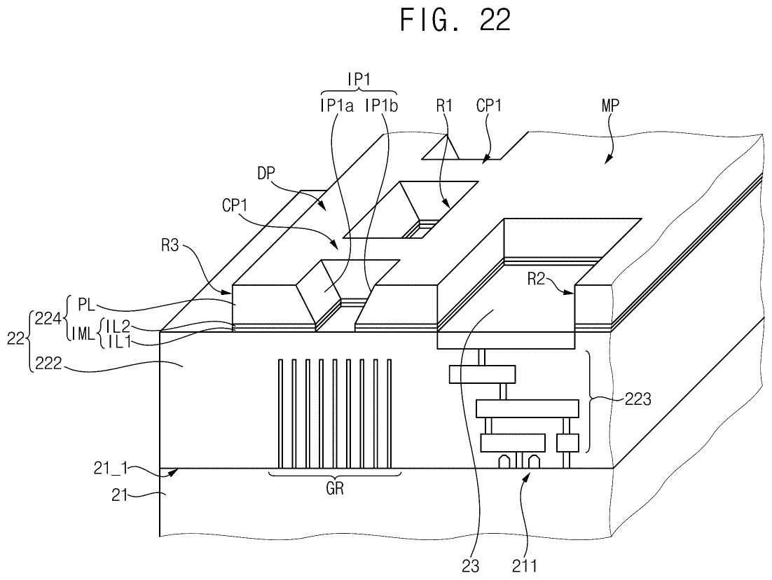

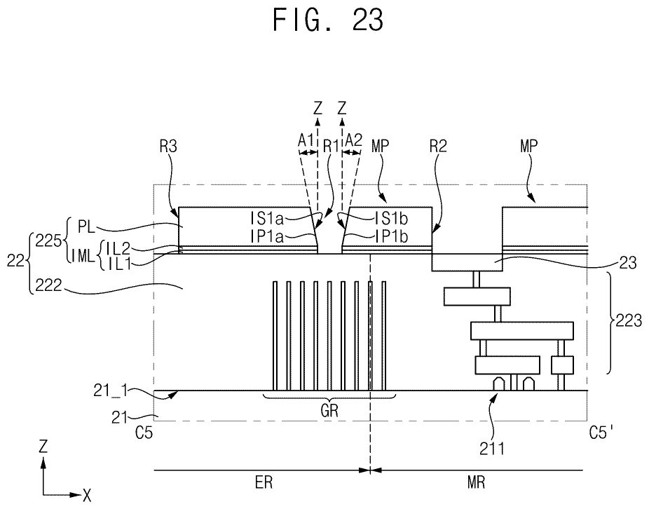

FIG. 21 is a plan view illustrating a passivation layer in accordance with example embodiments. FIG. 22 is a perspective view illustrating the second passivation layer in FIG. 21. FIG. 23 is a cross-sectional view taken along the line C5-C5′ in FIG. 21.

The semiconductor device 20 illustrated in FIGS. 21 to 23 is substantially the same as the semiconductor device 20 described in FIGS. 1 to 5, except for the second passivation layer 225, so identical components are denoted by the same reference numerals, and repeated descriptions of identical components are omitted.

Referring to FIGS. 21 to 23, the semiconductor device 20 may include a substrate 21, an insulation layer 22 provided on a front surface 21_1 of the substrate 21, a plurality of chip pads 23 provided within the insulation layer 22, and an adhesive film 27 provided on a backside surface 21_2 of the substrate 21, respectively.

The insulation layer 22 may include a front insulation layer 222 and a second passivation layer 225 sequentially stacked on the front surface 21_1 of the substrate 21. The insulation layer 22 may further include a plurality of wirings 223 (FIG. 22) provided on the central region MR of the front surface 21_1.

The second passivation layer 225 may include a plurality of interlayer insulation films IML and a photosensitive layer PL stacked sequentially on the front insulation layer 222. Further, the plurality of interlayer insulation films IML may include a first insulation layer IL1 and a second insulation layer IL2 stacked sequentially.

The second passivation layer 225 may include a central region MR overlapped with a protective layer MP to expose the plurality of chip pads 23, a crack prevention dam DP positioned within an edge region ER surrounding the central region MR and spaced apart from the central region MP, and a plurality of first stress distribution connectors CP1 connecting the protective layer MP and the crack prevention dam DP, respectively.

The second passivation layer 225 may include a plurality of first slits R1 disposed between the protection layer MP and the crack prevention dam DP, respectively, and provided on both side portions of each of the plurality of first stress distribution connectors CP1, a plurality of second slits R2 disposed within the central region MR to expose each of the plurality of chip pads 23, and a third slit R3 surrounding the crack prevention dam DP along the plurality of side portions S1, S2, S3, S4.

The second passivation layer 225 may further include a pair of first inclined portions IP1a and IP1b respectively provided within the plurality of first slits R1.

The pair of first inclined portions IP1a and IP1b may extend in a direction perpendicular to the plurality of first stress distribution connectors CP1, and the pair of first inclined portions IP1a and IP1b may connect between the plurality of first stress distribution connectors CP1, respectively. For example, the pair of first inclined members IP1a and IP1b may extend in a first direction (Y direction) and the plurality of first stress distribution connectors CP1 may extend in a second direction (X direction) perpendicular to the first direction (Y direction).

The pair of first inclined portions IP1a and IP1b may include a first inclined surface IS1a and a second inclined surface IS2a facing each other. For example, the first inclined surface IS1a and the second inclined surface IS2a may be respectively provided in the plurality of first slits R1 to face each other along the second direction (X direction).

For example, a first angle A1 of a first inclined structure IP1a (FIG. 23) may be within range from ‘0 degrees’ and ‘90 degrees’ with respect to the vertical direction (Z direction). And, a second angle A2 of a second inclined structure IP1b (FIG. 23) may be within range from ‘0 degrees’ and ‘90 degrees’ with respect to the vertical direction (Z direction).

For example, each of the plurality of first slits R1 may have the first inclined surface IS1a as a portion of an inner side surface IN of the crack prevention dam DP and the second inclined surface IS2a as a portion of an outer side surface OS of the protection layer MP.

Thus, the pair of first inclined portions IP1a and IP1b may effectively distribute or reduce the external force, and the pair of first inclined portions IP1a and IP1b may prevent the external force, which is transmitted to the crack prevention dam DP, from being transmitted to the central region MR.

Hereinafter, a method for manufacturing the second passivation layer 225 in FIG. 21 will be described.

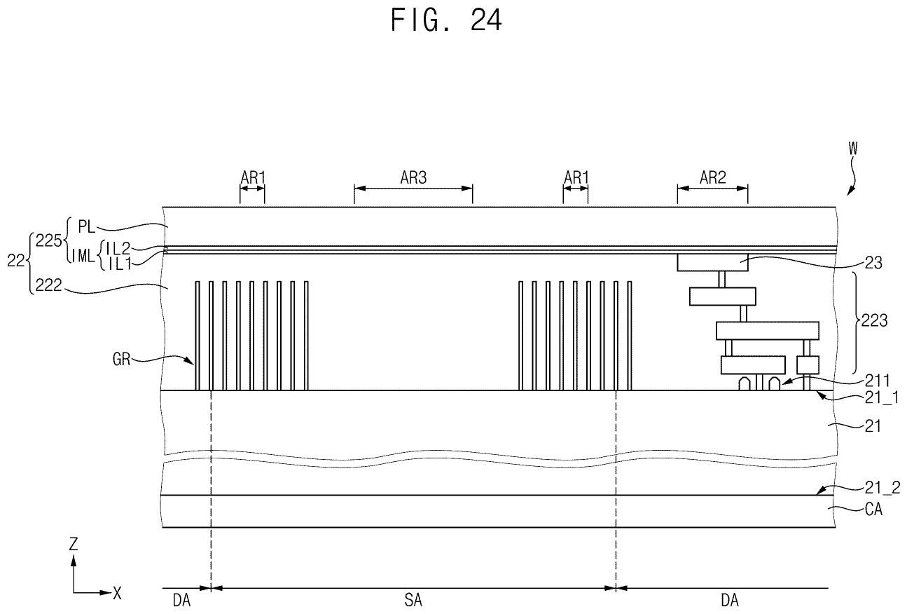

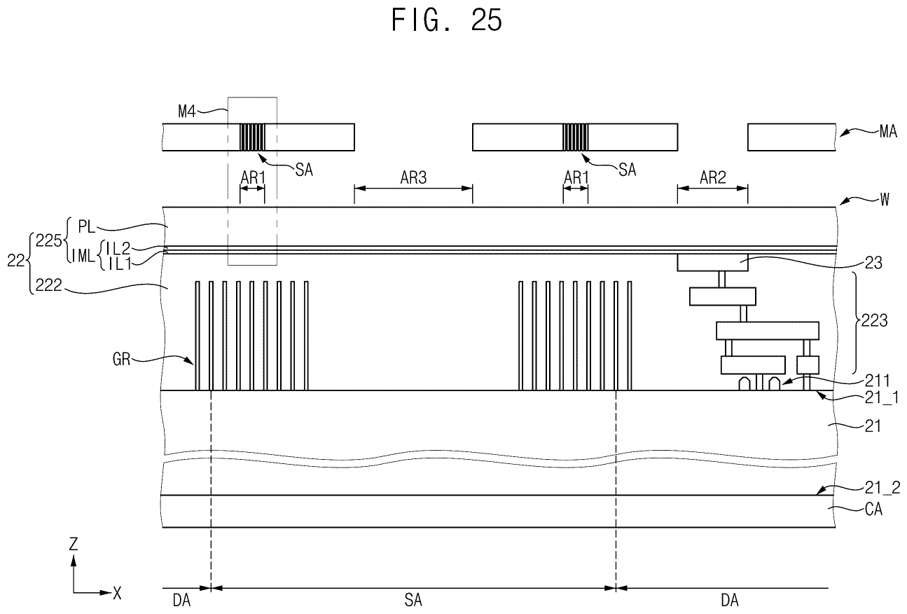

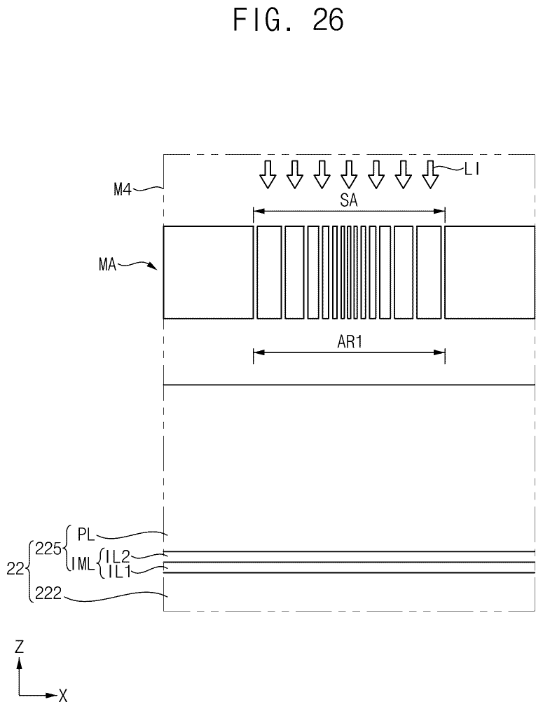

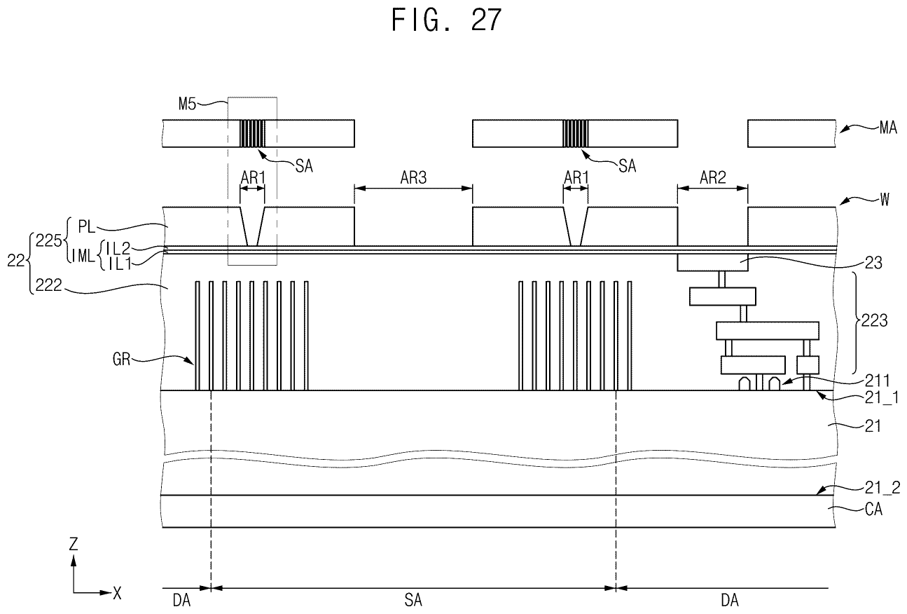

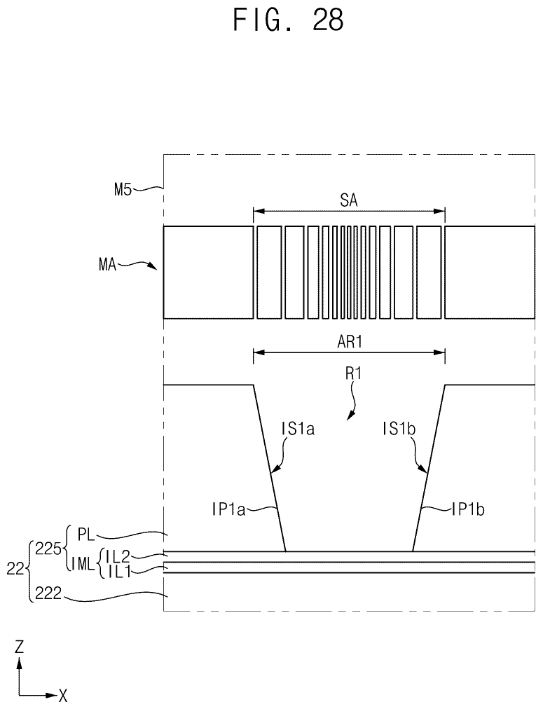

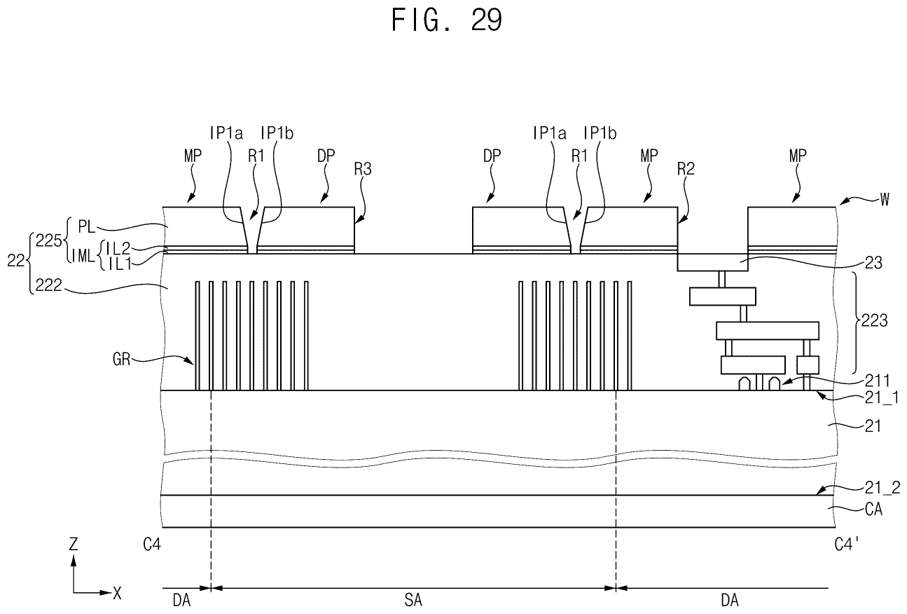

FIG. 24 is a cross-sectional view illustrating providing a wafer having a passivation layer in accordance with an example embodiment. FIG. 25 is a cross-sectional view illustrating positioning a mask on an upper portion of the passivation layer in FIG. 24 and irradiating light to the mask. FIG. 26 is an enlarged cross-sectional view illustrating ‘M4’ portion in FIG. 25. FIG. 27 is a cross-sectional view illustrating partially removing the passivation layer in FIG. 24. FIG. 28 is an enlarged cross-sectional view illustrating ‘M5’ portion in FIG. 27. FIG. 29 is an enlarged cross-sectional view illustrating partially removing the passivation layer in FIG. 27 to form slits exposing a front insulation layer.

The passivation layer manufactured by the manufacturing process described in FIGS. 24 to 29 is substantially identical to the second passivation layer 225 described in FIGS. 21 to 23, so identical components are denoted by the same reference numerals, and repeated descriptions of identical components are omitted.

Referring to FIGS. 24 to 26, an exposure process may be performed on the second passivation layer 225 to selectively irradiate light onto the first regions AR1, second regions AR2, and third region AR3.

For example, a mask MA having a pattern corresponding to the first regions AR1, second regions AR2, and third region AR3 may be placed on upper portion of the second passivation layer 225, and light may be irradiated onto the second passivation layer 225 through the mask MA to selectively irradiate only the first regions AR1, the second regions AR2, and third region AR3. Thus, light-irradiated portions of the second passivation layer 225 may have weakened bonds between materials.

In this case, the mask MA may include openings at regions corresponding to the second regions AR2 and the third region AR3, the openings allowing all light to pass through. Further, the mask MA may include a plurality of passing slits SA configured to pass only a portion of the light through regions corresponding to the first regions AR1. The plurality of passing slits may be spaced apart depending on the amount of light to be passed through. For example, a spacing distance between the passing slits may be narrowed in a region where a lot of light is to be transmitted, that is, an area where a lot of the second passivation layer 225 is to be removed. Conversely, a spacing distance between the passing slits may be wider in a region where less light is to be transmitted, that is, an area where less of the second passivation layer 225 is to be removed.

Thus, side portions of each of the plurality of first regions AR1 may receive less light, and center portion of each of the plurality of first regions AR1 may receive more light.

Referring to FIGS. 27 and 28, a developer may be provided on upper portion of the second passivation layer 225 to partially remove the first regions AR1, the second regions AR2, and third regions AR3. The plurality of first slits R1, the plurality of second slits R2, and the third slit R3 may expose the plurality of interlayer insulation films IML.

In this case, each of the plurality of first regions AR1 may be removed in proportion to the amount of light irradiated such that a pair of first inclined portions IP1a and IP1b may be formed within the plurality of first slits R1. For example, the side portions of each of the plurality of first regions AR1 may receive less light to be removed less, and the center portion of each of the plurality of first regions AR1 may receive more light to be removed more.

Referring to FIG. 29, an etching process may be performed on the plurality of interlayer insulation films IML, which are exposed by the plurality of first slits R1, the plurality of second slits R2, and the third slit R3, to form a pattern in the second passivation layer 225.

For example, the etching process may be a dry etching process in which a gas is injected onto the plurality of interlayer insulation films IML to partially remove the plurality of interlayer insulation films IML. The gas may include a material such as carbon tetrafluoride (CF4), etc.

While FIGS. 24 to 29 illustrate that the second passivation layer 225 is a positive type of photosensitive material in which the bonding of the illuminated portion is weakened, it will be appreciated that the present embodiments are not limited to this configuration. Thus, the second passivation layer 225 may be a negative type of photosensitive material in which the bonding of the illuminated portion is strengthened. In this case, the mask MA may have a pattern that selectively blocks light only to the first regions AR1, the second regions AR2, and the third region AR3.

Hereinafter, a third passivation layer 226 in accordance with example embodiments will be described.

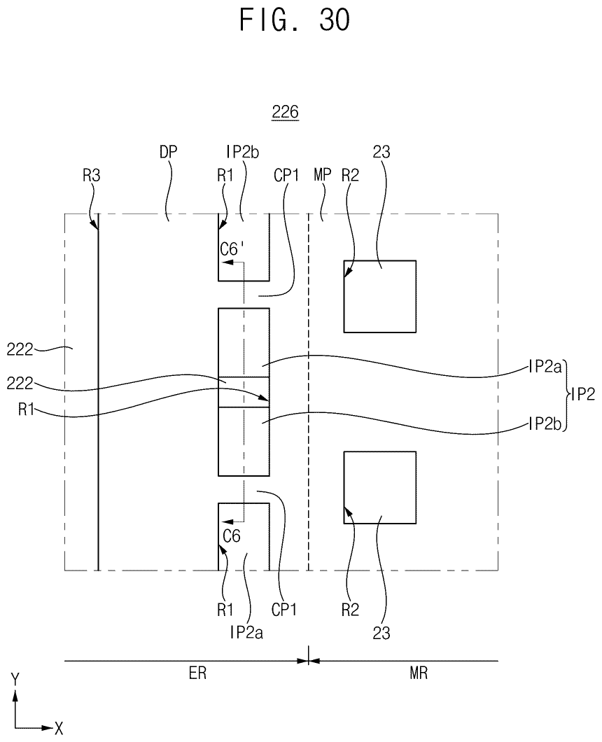

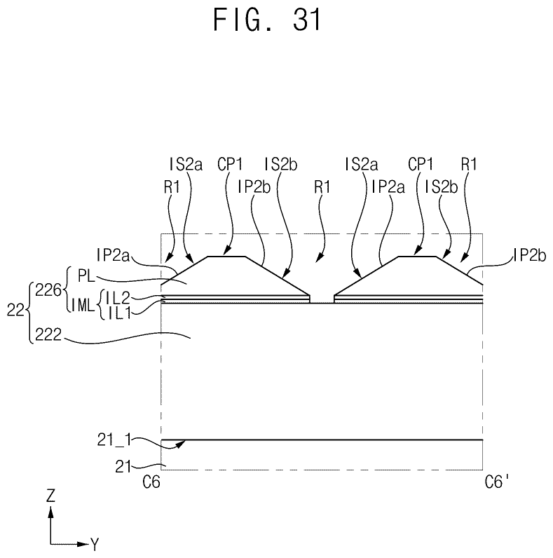

FIG. 30 is a plan view illustrating a passivation layer in accordance with example embodiments. FIG. 31 a cross-sectional view taken along the line C6-C6′ in FIG. 30.

The semiconductor device 20 described in FIGS. 30 and 31 is substantially the same as the semiconductor device 20 described in FIGS. 1 to 5, except for the third passivation layer 226, so identical components are denoted by the same reference numerals, and repeated descriptions of identical components are omitted.

Referring to FIGS. 30 and 31, the semiconductor device 20 may include a substrate 21, an insulation layer 22 provided on a front surface 21_1 of the substrate 21, a plurality of chip pads 23 provided within the insulation layer 22, and an adhesive film 27 provided on a backside surface 21_2 of the substrate 21, respectively.

The insulation layer 22 may include a front insulation layer 222 and a third passivation layer 226 sequentially stacked on the front surface 21_1 of the substrate 21.

The third passivation layer 226 may include a plurality of interlayer insulation films IML and a photosensitive layer PL stacked sequentially on the front insulation layer 222. Further, the plurality of interlayer insulation films IML may include a first insulation film IL1 and a second insulation film IL2 stacked sequentially.

The third passivation layer 226 may include a protection layer MP covering a central region MR of the substrate 21 and exposing the plurality of chip pads 23, a crack prevention dam DP extending to surround the protection layer MP within an edge region ER of the substrate 21 and spaced apart from the protection layer MP, and a plurality of first stress distribution connectors CP1 connecting the protection layer MP and the crack prevention dam DP, respectively.

The third passivation layer 226 may include a plurality of first slits R1 disposed between the protection layer MP and the crack prevention dam DP, respectively, and provided on both side portions of each of the plurality of first stress distribution connectors CP1, a plurality of second slits R2 disposed within the central region MR and exposing each of the plurality of chip pads 23, and a third slit R3 surrounding the crack prevention dam DP along the plurality of side portions S1, S2, S3, S4.

The first slits may include a first surface as a portion of the inner side surface IN of the crack prevention dam DP and a second surface as a portion of the outer side surface OS of the protection layer MP. For example, the first surface and the second surface may be perpendicular to an extension direction of the first stress distribution connector.

The third passivation layer 226 may further include a pair of second inclined portions IP2a and IP2b respectively provided within the plurality of first slits R1.

The pair of second inclined portions IP2a and IP2b may be disposed to face a center portion of the plurality of first slits R1. For example, the pair of second inclined portions IP2a and IP2b may include a third inclined surface IS2a and a fourth inclined surface IS2b facing each other. The third inclined surface IS2a and the fourth inclined surface IS2b may be provided in the plurality of first slits R1 to face each other along the first direction (Y direction).

The third inclined surface and the fourth inclined surface may be perpendicular to the first surface and the second surface of each of the first slits R1, and the third inclined surface and the fourth inclined surface may define the first slit together with the first surface and the second surface.

Thus, the pair of second inclined portions IP2a and IP2b may effectively distribute or reduce the external force, thereby preventing the external force, which is transmitted to the crack prevention dam DP, from being transmitted to the central region MR.

Hereinafter, a fourth passivation layer 227 in accordance with example embodiments will be described.

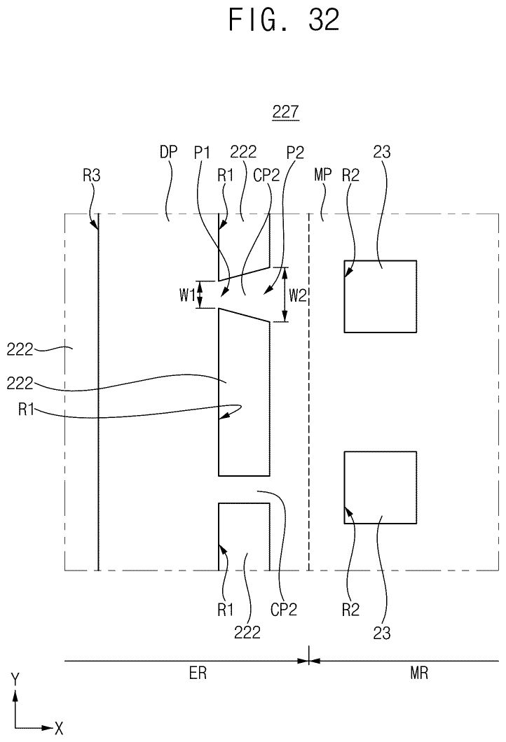

FIG. 32 is a plan view illustrating a passivation layer in accordance with example embodiments.

The fourth passivation layer 227 described in FIG. 32 is substantially the same as the first passivation layer 224 described in FIGS. 1 to 5, except for the plurality of second stress distribution connectors CP2, so identical components are denoted by the same reference numerals, and repeated descriptions of identical components are omitted.

Referring to FIG. 32, the fourth passivation layer 227 may include a protection layer MP covering a central region MR of the substrate 21 and exposing a plurality of chip pads 23, an crack prevention dam DP extending within an edge region ER of the substrate 21 to surround the protection layer MP and spaced apart from the protection layer MP, and a plurality of second stress distribution connectors CP2 connecting the protection layer MP and the crack prevention dam DP, respectively.

The fourth passivation layer 227 may include a plurality of first slits R1 disposed between the protection layer MP and the crack prevention dam DP and provided on both side portions of each of the plurality of second stress distribution connectors CP2, a plurality of second slits R2 disposed within the central region MR of the substrate 21 and exposing each of the plurality of chip pads 23, and a third slit R3 surrounding the crack prevention dam DP along the plurality of side portions S1, S2, S3, S4.

For example, each of the plurality of second stress distribution connectors may extend from an outer side surface OS of the protection layer MP to an inner side surface IN of the crack prevention dam DP, and the plurality of second stress distribution connectors may be spaced apart from each other along the outer side surface OS of the protection layer MP to form a first slit of quadrilateral.

The plurality of second stress distribution connectors CP2 may include a first portion P1 connecting to the crack prevention dam DP and a second portion P2 connecting to the protection layer MP. The first portion P1 may have a first width W1, and the second portion P2 may have a second width W2. For example, the first width may be different from the second width. Thus, each of the plurality of second stress distribution connectors may have a trapezoidal shape, when viewed in a plan view.

The second width W2 may be larger than the first width W1. Thus, the external force, which is transmitted from the crack prevention dam DP to the central region MR, may be effectively distributed, and cracks in the central region MR may be prevented. Furthermore, the plurality of second stress distribution connectors CP2 may effectively prevent the lifting phenomenon in which the crack prevention dam DP is separated from the front insulation layer 222.

While the figures only illustrate that the second width W2 is greater than the first width W1, it will be appreciated that the present embodiments are not limited thereto. Thus, the second width W2 may be less than the first width W1.

In one or more examples, the fourth passivation layer 227 may include a pair of first inclined portions (IP1a and IP1b, illustrated in FIG. 21) or a pair of second inclined portions (IP2a and IP2b, illustrated in FIG. 30) within the plurality of first slits R1.

Hereinafter, a fifth passivation layer 228 in accordance to example embodiments will be described.

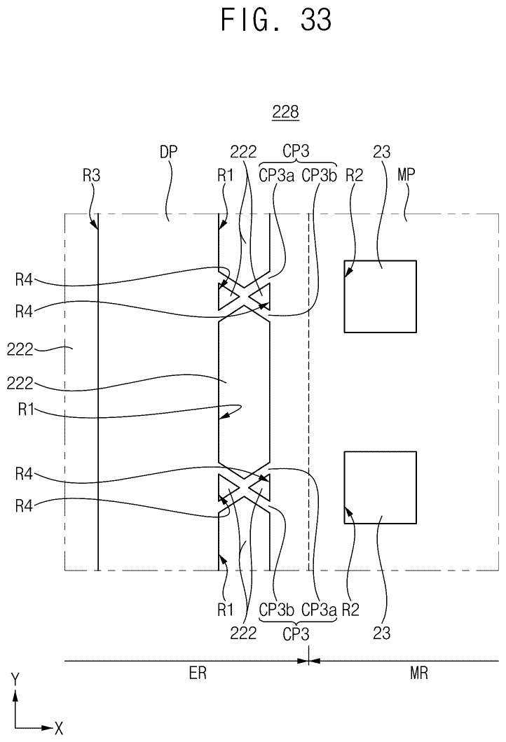

FIG. 33 is a plan view illustrating a passivation layer in accordance with example embodiments.

The fifth passivation layer 228 described in FIG. 33 is substantially the same as the first passivation layer 224 described in FIGS. 1 to 5, except for the plurality of third stress distribution connectors CP3, so identical components are denoted by the same reference numeral, and repeated descriptions of identical components are omitted.

Referring to FIG. 33, the fifth passivation layer 228 may include a protection layer MP covering a central region MR of the substrate 21 and exposing a plurality of chip pads 23, a crack prevention dam DP extending within an edge region ER of the substrate 21 to surround the protection layer MP and spaced apart from the protection layer MP, and a plurality of third stress distribution connectors CP3 connecting the protection layer MP and the crack prevention dam DP, respectively.

The fifth passivation layer 228 may include a plurality of first slits R1 disposed between the protection layer MP and the crack prevention dam DP and provided both side portions of each of the plurality of third stress distribution connectors CP3, and a plurality of second slits R2 disposed within the central region MR and exposing each of the plurality of chip pads 23, a third slit R3 surrounding the crack prevention dam DP along the plurality of side portions S1, S2, S3, S4, and a pair of fourth slits R4 provided within each of the plurality of third connectors CP3.

For example, each of the plurality of third stress distribution connectors may extend from an outer side surface OS of the protection layer MP to an inner side surface IN of the crack prevention dam DP, and the plurality of third stress distribution connectors may be spaced apart from each other along the outer side surface OS of the protection layer MP to form the plurality of first slits.

Each of the plurality of third stress distribution connectors CP3 may include a pair of connecting bars CP3a and CP3b extending in different directions and intersecting each other. The pair of connecting bars CP3a, CP3b may include a first connecting bar CP3a and a second connecting bar CP3b connecting the crack prevention dam DP and the protection layer MP, respectively.

The first connecting bar CP3a and the second connecting bar CP3b may be partially overlapped with each other. For example, center portions of each of the first connecting bar CP3a and the second connecting bar CP3b may be overlapped, and a pair of fourth slits R4 may be disposed between end portion of each of the first connecting bar CP3a and end portion of each of the second connecting bar CP3b so that the end portion of each of the first connecting bar CP3a and the end portion of each of the second connecting bar CP3b may be spaced apart from each other. Thus, each of the plurality of third stress distribution connectors may have an ‘X’ shape, when viewed in a plan view.

Thus, the plurality of third stress distribution connectors CP3 may effectively distribute external forces, which is transmitted from the crack prevention dam DP to the central region MR, thereby preventing cracks from occurring in the central region MR. Furthermore, the plurality of third stress distribution connectors CP3 may effectively prevent the lifting phenomenon in which the crack prevention dam DP is separated from the front insulation layer 222.

In one or more examples, the fifth passivation layer 228 may include a pair of first inclined portions (IP1 and IP1b, illustrated in FIG. 21) or a pair of second inclined portions (IP2a and IP2b, illustrated in FIG. 30) within the plurality of first slits R1.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present embodiments. Accordingly, all such modifications are intended to be included within the scope of example embodiments as defined in the claims.

What is claimed is:

1. A semiconductor device, comprising:
a substrate including a central region and an edge region surrounding the central region; and
a passivation layer on the substrate,
wherein the passivation layer comprises:
a protection layer covering the central region of the substrate,
a crack prevention dam extending in the edge region of the substrate to surround the protection layer, the crack prevention dam spaced apart from the protection layer, and
a plurality of stress distribution connectors extending from an outer side surface of the protection layer to an inner side surface of the crack prevention dam, each stress distribution connector from the plurality of stress distribution connectors spaced apart from each other along the outer side surface of the protection layer to form a slit defined by at least four sides.

2. The semiconductor device of claim 1, wherein each of the plurality of stress distribution connectors comprise a first portion connected to the crack prevention dam and a second portion connected to the protection layer, and
wherein the first portion has a first width and the second portion has a second width.

3. The semiconductor device of claim 2, wherein the first width is equal to the second width.

4. The semiconductor device of claim 2, wherein the first width is less than the second width.

5. The semiconductor device of claim 2, wherein the first width is greater than the second width.

6. The semiconductor device of claim 1, wherein the slit comprises (i) a first inclined surface as a portion of the inner side surface of the crack prevention dam and (ii) a second inclined surface as a portion of the outer side surface of the protection layer.

7. The semiconductor device of claim 1, wherein each of the plurality of stress distribution connectors comprises a pair of connecting bars extending in different directions and intersecting each other.

8. The semiconductor device of claim 1, further comprising:
a front insulation layer on the substrate,
wherein the passivation layer is on the front insulation layer.

9. The semiconductor device of claim 8, wherein the front insulation layer comprises a plurality of guide rings that extend from the central region to the edge region.

10. The semiconductor device of claim 8, further comprising:
a plurality of chip pads provided in the front insulation layer,
wherein the plurality of chip pads are arranged along a side portion of the central region.

11. A semiconductor device, comprising:
a substrate including a central region and an edge region surrounding the central region;
a front insulation layer on the substrate;
a plurality of chip pads in the front insulation layer, the plurality of chip pads arranged along a side portion of the central region; and
a passivation layer on the front insulation layer,
wherein the passivation layer comprises:
a protection layer covering the central region of the substrate,
a crack prevention dam extending in the edge region of the substrate to surround the protection layer, the crack prevention dam spaced apart from the protection layer, and
a plurality of stress distribution connectors extending from an outer side surface of the protection layer to an inner side surface of the crack prevention dam, each stress distribution connector form the plurality of stress distribution connectors spaced apart from each other along the outer side surface of the protection layer to form a slit defined by at least four sides.

12. The semiconductor device of claim 11, wherein each of the plurality of stress distribution connectors comprise a first portion connected to the crack prevention dam and a second portion connected to the protection layer,
wherein the first portion has a first width and the second portion has a second width.

13. The semiconductor device of claim 12, wherein the first width is equal to the second width.

14. The semiconductor device of claim 12, wherein the first width is less than the second width.

15. The semiconductor device of claim 12, wherein the first width is greater than the second width.

16. The semiconductor device of claim 11, wherein the slit comprises (i) a first inclined surface as a portion of the inner side surface of the crack prevention dam and (ii) a second inclined surface as a portion of the outer side surface of the protection layer.

17. The semiconductor device of claim 11, wherein each of the plurality of stress distribution connectors comprises a pair of connecting bars extending in different directions and intersecting each other.

18. The semiconductor device of claim 11, wherein the front insulation layer comprises a plurality of guide rings that extend from the central region to the edge region.

19. The semiconductor device of claim 11, wherein the slit comprises a pair of inclined surfaces extending from each of the stress distribution connectors in a direction perpendicular to an extending direction of each of the stress distribution connectors.

20. A semiconductor device, comprising:
a substrate including a central region and an edge region surrounding the central region;
a front insulation layer on a front surface of the substrate;
a plurality of chip pads in the front insulation layer, the plurality of chip pads arranged along a side portion of the central region;
a passivation layer on the front insulation layer; and
an adhesive film on a backside surface of the substrate,
wherein the passivation layer comprises:
a protection layer covering the central region of the substrate,
a crack prevention dam extending in the edge region of the substrate to surround the protection layer, the crack prevention dam spaced apart from the protection layer, and
a plurality of stress distribution connectors extending from an outer side surface of the protection layer to an inner side surface of the crack prevention dam, each stress distribution connector from the plurality of stress distribution connectors spaced apart from each other along the outer side surface of the protection layer,
wherein each of the plurality of stress distribution connectors comprise (i) a first portion connected to the crack prevention dam and (ii) a second portion connected to the protection layer and having a second width,
wherein the first portion has a first width and the second portion has a second width, and
wherein the first width is equal to the second width.
